(19) United States
(12) Patent Application Publication
(10) Pub. No.: US 2013/0149830 A1
(43) Pub. Date: Jun. 13, 2013

(54) METHODS OF FORMING FIELD EFFECT TRANSISTORS HAVING SILICON-GERMANIUM SOURCE/DRAIN REGIONS THEREIN

(71) Applicants: Hwa-Sung RHEE, Seongnam-si (KR); Seung-Chul Lee, Seongnam-si (KR); Chul-Wan An, Yongin-si (KR); Henry K. Utomo, Newburgh, NY (US); Seong-Dong Kim, LaGrangeville, NY (US)

(72) Inventors: Hwa-Sung RHEE, Seongnam-si (KR); Seung-Chul Lee, Seongnam-si (KR); Chul-Wan An, Yongin-si (KR); Henry K. Utomo, Newburgh, NY (US); Seong-Dong Kim, LaGrangeville, NY (US)

(73) Assignee: Samsung Electronics Co., Ltd.

(21) Appl. No.: 13/313,881

(22) Filed: Dec. 7, 2011

(51) Int. Cl. H01L 21/336

(52) U.S. Cl. 438/303; 257/E21.409

(57) ABSTRACT

Methods of forming field effect transistors include selectively etching source and drain region trenches into a semiconductor region using a gate electrode as an etching mask. An epitaxial growth process is performed to fill the source and drain region trenches. Silicon germanium (SiGe) source and drain regions may be formed using an epitaxial growth process. During this growth process, the bottoms and sidewalls of the trenches may be used as “seeds” for the silicon germanium growth. An epitaxial growth step may then be performed to define silicon capping layers on the SiGe source and drain regions.

### FIELD OF THE INVENTION

The present invention relates to methods of forming integrated circuit devices and, more particularly, to methods of forming field effect transistors.

### BACKGROUND OF THE INVENTION

Conventional methods of forming field effect transistors frequently include techniques to form complementary metal oxide semiconductor (CMOS) transistors. In particular, CMOS fabrication methods frequently include forming N-channel MOS transistors (NMOS) and P-channel MOS transistors (PMOS) at side-by-side locations in a semiconductor substrate. However, because NMOS and PMOS transistors typically have different characteristics (e.g., channel mobility, threshold voltage, etc.), CMOS fabrication methods may require the use of masking, implantation and other steps that are unique to either PMOS transistor formation or NMOS transistor formation. For example, a technique to increase a mobility of charge carriers in a channel of a PMOS transistor may include the establishment of stress in the channel. One technique for generating stress in the channel of a PMOS transistor includes establishing a lattice mismatch between a material of the channel, which may be formed of silicon (Si), and a material of the source/drain regions, which may be formed of silicon germanium (SiGe). Unfortunately, because the magnitude of the stress in the channel of a PMOS transistor may be function of the volume of SiGe in the source/drain regions, CMOS fabrication steps that cause a reduction in the volume of the SiGe source/drain regions may significantly reduce PMOS transistor yield and performance.

### SUMMARY OF THE INVENTION

Methods of forming field effect transistors according to some embodiments of the invention include selectively etching source and drain region trenches into a semiconductor region using a gate electrode as an etching mask. These trenches may have depths in a range from about 500-600 Å, for example. An epitaxial growth process is then performed to fill the source and drain region trenches. In particular, silicon germanium (SiGe) source and drain regions may be formed in the trenches using an epitaxial growth process. During this growth process, the bottoms and sidewalls of the trenches may be used as “seeds” for the silicon germanium growth. An epitaxial growth step may then be performed to define silicon capping layers on the SiGe source and drain regions. In some embodiments of the invention, the step of forming the silicon capping layers may be performed at a temperature in a range from about 700° C. to about 800° C. and may even include in-situ doping the silicon capping layers with carbon dopants. At least portions of these silicon capping layers may then be converted to respective silicide contact regions using a silicidation process.

According to additional embodiments of the invention, the step of forming the silicide contact regions may be preceded by implanting source and drain region dopants into the epitaxially-grown SiGe source and drain regions. In particular, the step of epitaxially growing the silicon capping layers from the SiGe source and drain regions may be preceded by implanting source and drain region dopants into the SiGe source and drain regions.

According to further embodiments of the invention, the gate electrode may include a nitride capping layer thereon and the step of epitaxially growing the silicon capping layers may be preceded by removing the nitride capping layer from the gate electrode using an etching process that also recesses the SiGe source and drain regions. Alternatively, the nitride capping layer may be removed after the silicon capping layers are epitaxially grown on the SiGe source and drain regions.

According to still further embodiments of the invention, the step of forming silicide contact regions includes forming silicide contact regions on upper surfaces of the silicon capping layers, which are elevated relative to a surface of the semiconductor region upon which the gate electrode is formed.

Additional methods of forming field effect transistors according to embodiments of the invention may include forming an insulated gate electrode on a semiconductor active region and covering the insulated gate electrode with a first silicon nitride spacer layer. The first silicon nitride spacer layer is then selectively etched using a reactive ion etching (RIE) technique that yields first nitride spacers on sidewalls of the insulated gate electrode and source/drain recesses in the semiconductor active region. The insulated gate electrode and the first nitride spacers are then covered with a second silicon nitride spacer layer. This second silicon nitride spacer layer is then selectively etched to yield second nitride spacers on sidewalls of the insulated gate electrode and further deepen the source/drain recesses in the semiconductor active region. These source/drain recesses are then at least partially filled by epitaxially growing silicon capping layers therein and forming silicide contact regions on the silicon capping layers. Moreover, in the event the insulated gate electrode includes a nitride capping layer thereon, the step of filling the source/drain recesses may be preceded by a step to remove the nitride capping layer using a reactive ion etching technique that also deepens the source/drain recesses.

### BRIEF DESCRIPTION OF THE DRAWINGS

FIG. 1A is a flow diagram of process steps that illustrates methods of forming field effect transistors according to embodiments of the invention.

FIG. 1B is a flow diagram of process steps that illustrates methods of forming field effect transistors according to embodiments of the invention.

FIGS. 2A-2E are cross-sectional views of intermediate structures that illustrate methods of forming field effect transistors according to embodiments of the invention.

FIGS. 3A-3G are cross-sectional views of intermediate structures that illustrate methods of forming field effect transistors according to embodiments of the invention.

### DESCRIPTION OF PREFERRED EMBODIMENTS

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

It will be understood that when an element or layer is referred to as being “on,” “connected to” or “coupled to” another element or layer (and variants thereof), it can be directly on, connected or coupled to the other element or layer or intervening elements or layers may be present. In contrast, when an element is referred to as being “directly on,” “directly connected to” or “directly coupled to” another element or layer (and variants thereof), there are no intervening elements or layers present. Like reference numerals refer to like elements throughout.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprising”, “including”, having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components.

Embodiments of the present invention are described herein with reference to cross-section and perspective illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a sharp angle may be somewhat rounded due to manufacturing techniques/tolerances.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

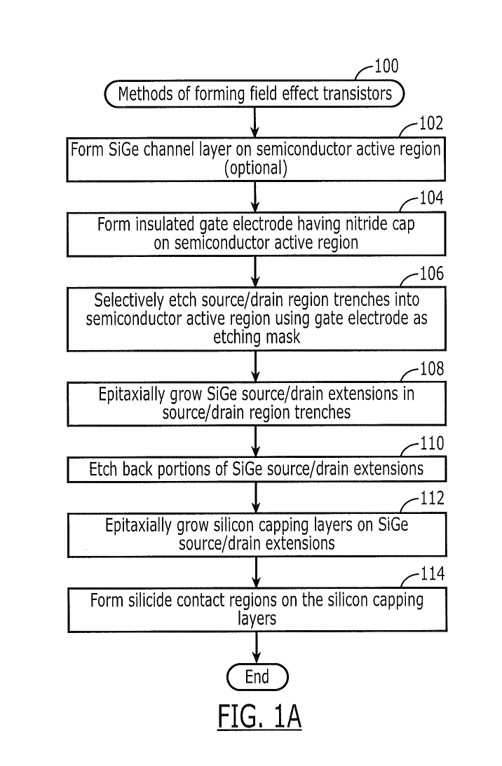

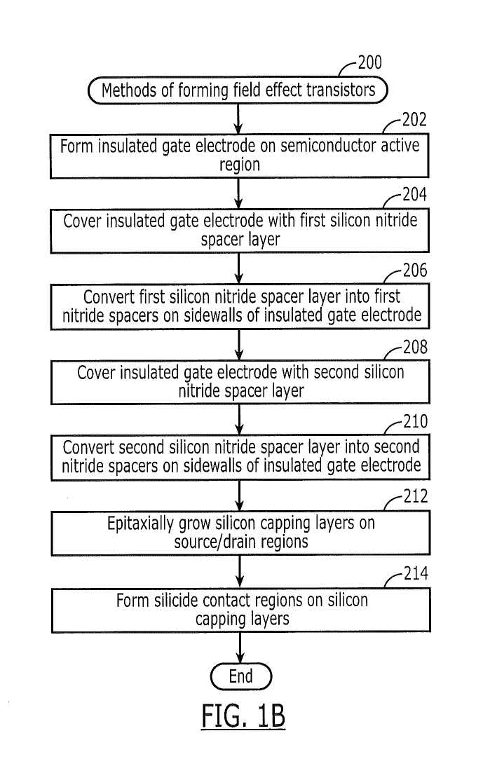

FIGS. 1A-1B are flow diagrams that illustrate methods of forming field effect transistors 100, 200 according to embodiments of the invention. As illustrated by FIG. 1A, first methods of forming a field effect transistor 100 may include forming a silicon germanium (SiGe) channel layer on an upper surface of a semiconductor active region (e.g., silicon active region) within a semiconductor substrate, Block 102. This SiGe channel layer may eliminate the need for lightly-doped source/drain extensions (i.e., LDD regions) within the active region. Thereafter, an insulated gate electrode having a nitride cap thereon is formed on the semiconductor active region, Block 104. As shown by Block 106, source and drain region trenches are etched into the active region using, for example, a reactive ion etching (RIE) technique. This reactive ion etching technique may use the gate electrode as an etching mask. Thereafter, as shown by Block 108, silicon germanium (SiGe) source and drain regions are epitaxially grown in the source and drain region trenches. Subsequent steps, such as those including the formation of sidewall spacers and nitride cap removal, may also result in an etch back of the SiGe source and drain regions, Block 110, which yield recesses therein. These recesses in the SiGe source and drain regions may be filled by epitaxially growing silicon capping layers on the SiGe source and drain regions, Block 112, and then converting at least portions of the epitaxial silicon capping layers into silicide capping layers, which may provide relatively low resistance contacts to the SiGe source and drain regions.

As illustrated by FIG. 1B, second methods of forming a field effect transistor 200 may include forming an insulated gate electrode on a semiconductor active region, Block 202, and then covering the insulated gate electrode with a first silicon nitride spacer layer, Block 204. This first silicon nitride spacer layer is converted into first silicon nitride spacers on sidewalls of the insulated gate electrode, Block 206. Thereafter, the insulated gate electrode is covered with a second silicon nitride spacer layer, Block 208, which is then converted into second silicon nitride sidewall spacers, Block 210. These steps of converting silicon nitride spacer layers into sidewall spacers may cause the formation of recesses in underlying source and drain regions, which are then filled with silicon capping layers using an epitaxial growth technique, Block 212. Silicide contact regions may then be formed on the epitaxially-grown silicon capping layers to thereby provide relatively low resistance contacts to the source/drain regions of the transistor, Block 214.

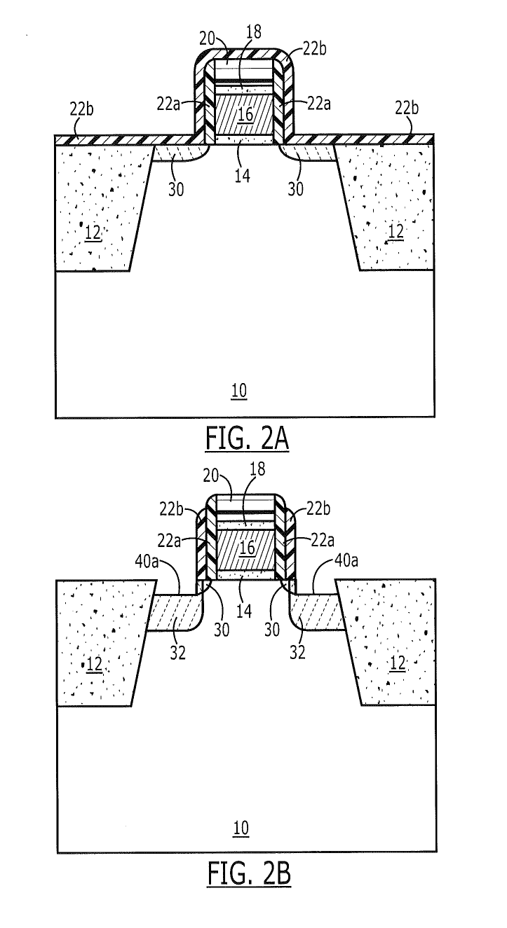

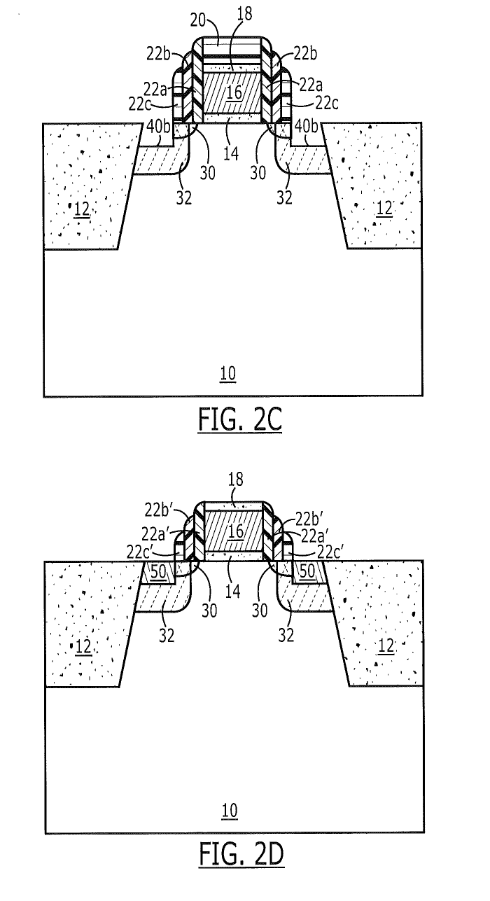

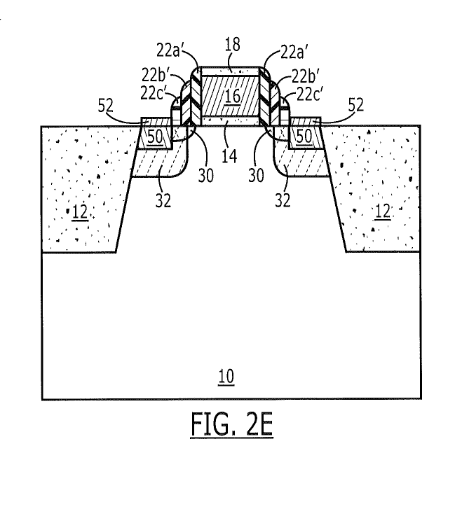

FIGS. 2A-2E illustrate methods of forming field effect transistors according to additional embodiments of the invention. As shown by FIG. 2A, a method of forming a field effect transistor (e.g., NMOS transistor) may include forming a plurality of shallow trench isolation (STI) regions 12 (e.g., oxide isolation regions) in a semiconductor substrate 10. The spacing of these STI regions 12 may be used to define a plurality of active device regions within the substrate 10. An insulated gate electrode is provided on a respective active device region (e.g., channel region). This insulated gate electrode may be initially configured from a patterned stack of layers, including a gate insulating layer 14 (e.g., gate oxide), a gate electrode 16 (e.g., doped or undoped polysilicon) on the gate insulating layer 14, an oxide cap 18 on the gate electrode 16 and a nitride cap 20 on the oxide cap 18. Electrically insulating spacers are also provided on opposing sidewalls of the insulated gate electrode. These insulating spacers may be formed as first nitride spacers 22a, which are covered by a nitride spacer layer 22b, as shown. Doped source/drain regions 30 (e.g., LDD regions), which are self-aligned to the insulated gate electrode, may be provided in the substrate 10 using conventional implantation and annealing techniques, for example. Thereafter, as shown by FIG. 2B, second nitride spacers 22b may be formed on the first nitride spacers 22a by anistropically etching the nitride spacer layer 22b shown in FIG. 2A. This anisotropic etching step may be performed as a reactive ion etching (RIE) step, which may result in the formation of source/drain recesses 40a in the substrate, as shown. These recesses 40a may have a depth of about 150 Å, for example. A halo implant (e.g., high angle implant) may also be performed to define source/drain halo regions. A source/drain doping step may also be performed by implanting source/drain dopants into the substrate at a relatively high dose and implant energy to thereby define relatively highly doped source/drain regions 32.

Referring now to FIG. 2C, a nitride layer (not shown) may be conformally deposited and then anisotropically etched using a reactive ion etching (RIE) technique to thereby define third nitride spacers 22c on the second nitride spacers 22b. The use of a reactive ion etching step may increase a depth of the source/drain recesses 40b. Thereafter, as shown by FIG. 2D, the nitride cap 20 may be removed using an etching step than may further deepen the source/drain recesses 40b (e.g., by 120-150 Å). In order to inhibit silicide-induced drain-to-source leakage currents (caused by silicide encroachment into a channel region of the transistor), a selective epitaxial growth (SEG) step may be performed to fill the source/drain recesses 40b with epitaxial silicon regions 50. In alternative embodiments of the invention, the selective epitaxial silicon growth step may be performed before the nitride cap 20 is removed and even possibly before the relatively highly doped source/drain regions 32 are defined.

According to additional embodiments of the invention, the epitaxial silicon regions 50 may be formed to define raised source/drain regions having upper surfaces that are elevated relative an upper surface of the substrate 10. These silicon regions 50 may also receive a separate source/drain implant in order to have a sufficiently high conductivity. As shown by FIG. 2E, a silicidation step may be performed to convert upper portions of the silicon regions 50 into highly conductive silicide source/drain contact regions 52.

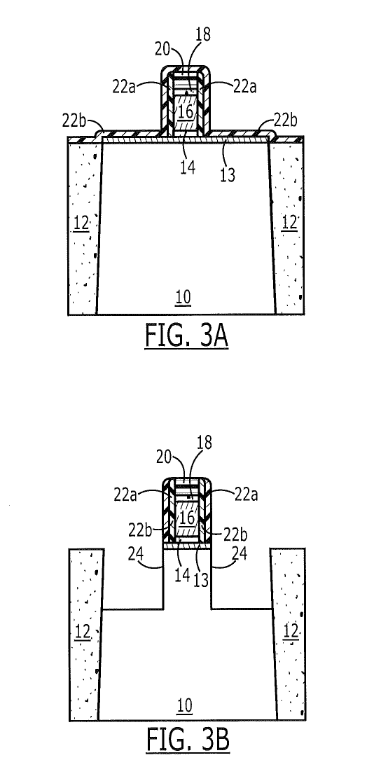

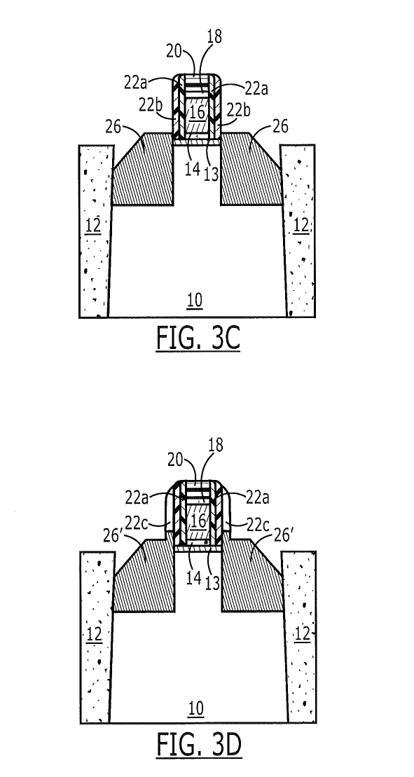

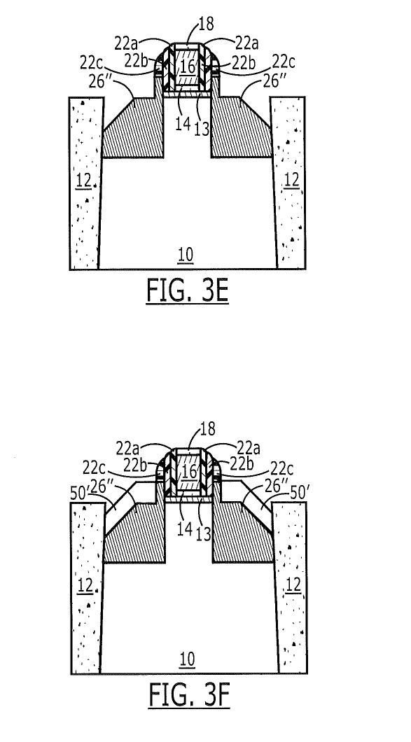

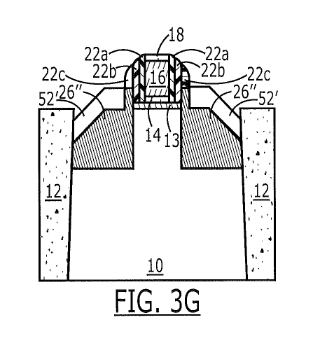

FIGS. 3A-3G illustrate methods of forming field effect transistors according to additional embodiments of the invention. These methods may be performed concurrently with the steps illustrated by FIGS. 2A-2E in order form complementary metal oxide semiconductor (CMOS) transistors. As shown by FIG. 3A, a method of forming a field effect transistor (e.g., PMOS transistor) may include forming a plurality of shallow trench isolation (STI) regions 12 (e.g., oxide isolation regions) in a semiconductor substrate 10. The spacing of these STI regions 12 may be used to define a plurality of active device regions within the substrate 10. In some embodiments of the invention, an upper surface of the substrate 10 extending between adjacent STI regions may receive a threshold voltage (Vth) implant or, as illustrated, a silicon germanium (SiGe) channel layer 13 (optional) may be provided on the upper surface using an epitaxial growth technique, for example. This use of a channel layer 13 may eliminate the need for forming relatively lightly doped source/drain extension regions.

As further illustrated by FIG. 3A, an insulated gate electrode is provided on a respective active device region. This insulated gate electrode may be initially configured from a patterned stack of layers, including a gate insulating layer 14 (e.g., gate oxide), a gate electrode 16 (e.g., doped or undoped polysilicon) on the gate insulating layer 14, an oxide cap 18 on the gate electrode 16 and a nitride cap 20 on the oxide cap 18. Electrically insulating spacers are also provided on opposing sidewalls of the insulated gate electrode. These insulating spacers may be formed as first nitride spacers 22a, which are covered by a nitride spacer layer 22b, as shown.

Thereafter, as shown by FIG. 3B, second nitride spacers 22b may be formed on the first nitride spacers 22a by anistropically etching the nitride spacer layer 22b shown in FIG. 3A. In addition, source and drain region trenches 24 are selectively etched into the substrate 10 using the gate electrode as an etching mask. This etching step, which may be an anisotropic reactive ion etching (RIE) step, may yield trenches 24 having a depth in a range from about a 500-600 Å. The etching step may also operate to recess an upper surface of the nitride cap 20.

As illustrated by FIG. 3C, SiGe source and drain regions 26 are formed in the trenches 24 by performing an epitaxial growth step that uses the bottoms and sidewalls of the trenches 24 as epitaxial “seeds.” This epitaxial growth step may include in-situ doping the SiGe source and drain regions 26 with source/drain region dopants, however, implant and annealing steps may be performed to increase a conductivity of the SiGe source and drain regions 26. Thereafter, as illustrated by FIG. 3D, a nitride layer (not shown) may be conformally deposited and then anisotropically etched using a reactive ion etching (RIE) technique to thereby define third nitride spacers 22c on the second nitride spacers 22b. The use of a reactive ion etching step in the formation of the third nitride spacers 22c may operate to recess the SiGe source and drain regions 26′. Likewise, the use of a reactive ion etching step to remove the nitride cap 20, as illustrated by FIG. 3E, may further recess the SiGe source and drain regions 26″.

Referring now to FIGS. 3F-3G, a selective epitaxial growth (SEG) step may be performed to at least partially fill-in the recesses in the SiGe source and drain regions 26″ with epitaxial silicon regions 50′. These epitaxial silicon regions 50′ may be formed at a temperature in a range between 700-800° C. Following the epitaxial growth step, a silicidation step may be performed to at least partially convert the silicon regions 50′ into silicide source/drain contact regions 52′.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A method of forming a field effect transistor, comprising:
selectively etching source and drain region trenches into a semiconductor region using a gate electrode as an etching mask;
epitaxially growing SiGe source and drain regions in the source and drain region trenches, respectively;
epitaxially growing silicon capping layers on the SiGe source and drain regions; and
forming silicide contact regions on the silicon capping layers.

2. The method of claim 1, wherein said forming silicide contact regions is preceded by implanting source and drain region dopants into the silicon capping layers.

3. The method of claim 1, wherein said epitaxially growing silicon capping layers is preceded by implanting source and drain region dopants into the SiGe source and drain regions.

4. The method of claim 1, wherein the gate electrode comprises a nitride capping layer; and wherein said epitaxially growing silicon capping layers is preceded by removing the nitride capping layer using an etching process that recesses the SiGe source and drain regions.

5. The method of claim 1, wherein the gate electrode comprises a nitride capping layer; and wherein said epitaxially growing silicon capping layers is followed by removing the nitride capping layer.

6. The method of claim 1, wherein the gate electrode is formed on a surface of the semiconductor region; and wherein said forming silicide contact regions comprises forming silicide contact regions on upper surfaces of the silicon capping layers that are elevated relative to the surface of the semiconductor region.

7. The method of claim 1, wherein said selectively etching comprises selectively etching source and drain region trenches having depths in a range from about 500 Å to about 600 Å into the semiconductor region.

8. The method of claim 1, wherein said epitaxially growing silicon capping layers comprises in-situ doping the silicon capping layers with carbon dopants.

9. The method of claim 1, wherein said epitaxially growing silicon capping layers on the SiGe source and drain regions comprises epitaxially growing silicon capping layers at a temperature in a range from about 700° C. to about 800° C.

10. The method of claim 1, wherein the field effect transistor is a PMOS transistor; and wherein said epitaxially growing silicon capping layers on the SiGe source and drain regions is performed concurrently with epitaxially growing silicon capping layers on source and drain regions of an NMOS transistor.

11. The method of claim 10, wherein said epitaxially growing silicon capping layers on the SiGe source and drain regions comprises epitaxially growing silicon capping layers at a temperature in a range from about 700° C. to about 800° C.

12. A method of forming a field effect transistor, comprising:
forming an insulated gate electrode on a semiconductor active region;
covering the insulated gate electrode with a first silicon nitride spacer layer;
selectively etching the first silicon nitride spacer layer using a reactive ion etching technique to thereby define first nitride spacers on sidewalls of the insulated gate electrode and source/drain recesses in the semiconductor active region;
covering the insulated gate electrode and the first nitride spacers with a second silicon nitride spacer layer;
selectively etching the second silicon nitride spacer layer using a reactive ion etching technique to thereby define second nitride spacers on sidewalls of the insulated gate electrode and deepen the source/drain recesses in the semiconductor active region;
epitaxially growing silicon capping layers on the source/drain recesses; and
forming silicide contact regions on the silicon capping layers.

13. The method of claim 12, wherein the field effect transistor is an NMOS transistor; and wherein said epitaxially growing silicon capping layers is performed concurrently with epitaxially growing silicon capping layers on epitaxially-grown silicon germanium source/drain regions of a PMOS transistor.

14. The method of claim 12, wherein the insulated gate electrode comprises a nitride capping layer; and wherein said epitaxially growing is preceded by removing the nitride capping layer using a reactive ion etching technique that further deepens the source/drain recesses in the semiconductor active region.

15. A method of forming a field effect transistor, comprising:
forming an insulated gate electrode on a semiconductor active region;
epitaxially growing SiGe source and drain region extensions on the semiconductor active region, at locations adjacent the insulated gate electrode;
epitaxially growing silicon capping layers on the SiGe source and drain region extensions; and
forming silicide contact regions on the silicon capping layers.

16. The method of claim 15, wherein said epitaxially growing silicon capping layers on the SiGe source and drain region extensions comprises epitaxially growing silicon capping layers at a temperature in a range from about 700° C. to about 800° C.

17. The method of claim 15, wherein said epitaxially growing silicon capping layers is preceded by implanting source and drain region dopants into the SiGe source and drain region extensions.

18. The method of claim 15, wherein the insulated gate electrode comprises a nitride capping layer; and wherein said epitaxially growing silicon capping layers is preceded by removing the nitride capping layer using an etching process that recesses the SiGe source and drain region extensions.

19. The method of claim 15, wherein the insulated gate electrode comprises a nitride capping layer; and wherein said epitaxially growing silicon capping layers is followed by removing the nitride capping layer.

20. The method of claim 15, wherein the insulated gate electrode is formed on a surface of the semiconductor action region; and wherein said forming silicide contact regions comprises forming silicide contact regions on upper surfaces of the silicon capping layers that are elevated relative to a surface of the semiconductor active region.
